(19) United States
(12) Patent Application Publication
(10) Pub. No.: US 2014/0284451 A1
(43) Pub. Date: Sep. 25, 2014

(54) REDUCING LOCALIZED HIGH ELECTRIC FIELDS IN PHOTOCONDUCTIVE WIDE BANDGAP SEMICONDUCTORS

(71) Applicant: LAWRENCE LIVERMORE NATIONAL SECURITY, LLC, Livermore, CA (US)

(72) Inventors: Stephen Sampayan, Manteca, CA (US); George J. Caporaso, Livermore, CA (US)

(73) Assignee: LAWRENCE LIVERMORE NATIONAL SECURITY, LLC, Livermore, CA (US)

(21) Appl. No.: 14/218,750

(22) Filed: Mar. 18, 2014

Related U.S. Application Data
(60) Provisional application No. 61/852,127, filed on Mar. 15, 2013.

(51) Int. Cl. H03C 1/34; H03C 7/02

(52) U.S. Cl. CPC H03C 1/34; H03C 7/025
USPC 250/206

(57) ABSTRACT

Methods, systems, and devices are disclosed for implementing a high voltage variable resistor. In one aspect, an optical transconductance variable resistor includes a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor, and first and second electrodes in contact with the material so that: a first triple junction boundary region is formed between the PWBSM substrate and the first electrode, and a second triple junction boundary region is formed between the PWBSM substrate and the second electrode, and the PWBSM substrate is located within an internal triple junction region formed between the first and second triple junction boundary regions.

### CROSS-REFERENCE TO RELATED APPLICATIONS

This patent document claims benefit of priority of U.S. Provisional Patent Application No. 61/852,127, entitled “SYSTEM AND METHOD OF MODULATING HIGH VOLTAGE ELECTRICAL SIGNALS USING PHOTOCONDUCTIVE WIDE BANDGAP SEMICONDUCTOR AS VARIABLE RESISTORS”, and filed on Mar. 15, 2013. The entire content of the aforementioned patent application is incorporated by reference as part of the disclosure of this patent document.

### STATEMENT REGARDING FEDERALLY SPONSORED RESEARCH OR DEVELOPMENT

The United States Government has rights in this invention pursuant to Contract No. DE-AC52-07NA27344 between the U.S. Department of Energy and Lawrence Livermore National Security, LLC, for the operation of Lawrence Livermore National Laboratory.

### TECHNICAL FIELD

This patent document relates to circuits, analog devices and telecommunication technologies.

### BACKGROUND

Electronic circuits in most applications are based on electronic circuit elements, such as resistors, capacitors, inductors, transistors, diodes and other circuit modules including amplifiers, oscillators, and switches that are based on the above circuit elements. Such circuits can be implemented in various configurations and can be used in various applications. Electric circuits entirely formed of electrical circuit elements can be limited due to device limitations in the circuit elements. For example, with the ever growing need for compact telecommunication equipment, there is a growing demand for efficient ways in which receiver and transmitter functions can be implemented.

### SUMMARY

Disclosed are devices, systems, and techniques that can be implemented to ensure that the electric field within an exemplary photoconductive wide bandgap semiconductor material (PWBSM)is sufficiently uniform so that the performance of a PWBSM-device is not degraded. Further, the disclosed technology can be implemented to ensure that there are no current flow concentrations so as to cause extreme localized heating which can lead to vaporization of electrode material and PWBSM, e.g. as such heating will result in eventual catastrophic failure within a device.

In one aspect, a surface of a photoconductive wide bandgap semiconductor material (PWBSM) that is in contact with an electrode is processed to form an electrically conductive layer that conforms to the surface of the PWBSM and forms an equal electrical potential surface. The electrode is placed in contact with the electrically conductive layer that conforms to the surface of the PWBSM as an electrode for the PWBSM. In this configuration, the interface between the electrode and the electrically conductive layer that conforms to the surface of the PWBSM is at a substantially equal electrical potential without localized electrical field enhancements that may cause undesired electrical breakdown under high voltage or high current operating conditions.

In another aspect, an optical transconductance variable resistor includes a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor, and first and second electrodes in contact with the material so that: a first triple junction boundary region is formed between the PWBSM substrate and the first electrode, and a second triple junction boundary region is formed between the PWBSM substrate and the second electrode, and the PWBSM substrate is located within an internal triple junction region formed between the first and second triple junction boundary regions.

In some implementations of the optical transconductance variable resistor, for example, the region outside the internal triple junction region is an insulator.

In another aspect, an optical transconductance variable resistor includes a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor, a first electrode and a second electrode in contact with the photoconductive wide bandgap semiconductor material, and in which one of the first and the second electrodes includes at least one aperture to control radiation to within a volume bounded by a triple junction region formed between a first triple junction region and a second triple junction region, in which the first triple junction region is formed between the PWBSM substrate and the first electrode, and the second triple junction boundary region is formed between the PWBSM substrate and the second electrode.

In some implementations of the optical transconductance variable resistor, for example, the variable resistor can further include a diffusion/dispersion structure is coated with a reflective coating to reflect radiation toward the substrate. In such implementations, for example, the variable resistor can further include a tapered light pipe connected to the at least one radiation aperture of the electrodes for diffusing/dispersing radiation prior to entering the aperture. In such implementations, for example, the electrode having aperture can expand, diffuse, and/or disperse the radiation into the triple junction region. In some implementations of the optical transconductance variable resistor, for example, the other electrode not having the aperture is reflective at the electrode-substrate interface.

The above and other aspects and their implementations are described in greater detail in the drawings, the description and the claims.

### BRIEF DESCRIPTION OF THE DRAWINGS

FIG. 1 shows a circuit based on a photoconductive wide bandgap semiconductor material (PWBSM).

FIG. 2 shows examples of measured photoconductive currents measured in sample SiC materials under different optical energy levels and under different applied voltages.

FIGS. 3, 4A, 4B and 5 show examples of PWBSM circuits and devices.

FIG. 6 illustrates an example of a non-conformal electrode-PWBSM interface.

FIG. 7 illustrates an example of a conformal conductive layer over the PWBSM interface to reduce localized field enhancements.

FIGS. 8A, 8B and 8C show an example of a process of forming a conformal conductive layer over a PWBSM interface and the subsequent formation of an electrode over the conformal conductive layer.

### DETAILED DESCRIPTION

A photoconductive wide bandgap semiconductor material (PWBSM) can be used to achieve extremely high electric fields in the material without failure and to conduct large currents because of the very low resistance in a photoconductive mode under proper optical excitation condition. For example, silicon carbide (SiC) can be used to create an electric field exceeding 200 kV/mm and achieve an on resistance of less than one ohm. Current densities of many thousands of amperes of current per square centimeter can therefore be achieved.

Silicon carbide is an example of various PWBSM materials. SiC has a high dielectric breakdown strength, greater than that of most solid materials (e.g., about 4 MV/cm); high thermal conductivity (comparable to that of copper); and low optical absorption. Single crystalline SiC materials can be used to implement a wide bandgap photoconductive switch in circuits and devices. Some examples of SiC and other wide bandgap photoconductive switches are disclosed in patent filings by Lawrence Livermore National Security, LLC, including U.S. patent application Ser. No. 13/830,741, entitled “PHOTOCONDUCTIVE SWITCH WITH IMPROVED LIFE SPAN”, filed on Mar. 14, 2013, PCT publication No. WO2010129804 A1, entitled “PHOTOCONDUCTIVE SWITCH PACKAGE” based on PCT application PCT/US2010/033923 filed May 6, 2010, which are incorporated by reference in their entirety as part of the disclosure of this patent document. Other examples of PWBSM materials include gallium nitride, aluminum nitride, boron nitride, and diamond.

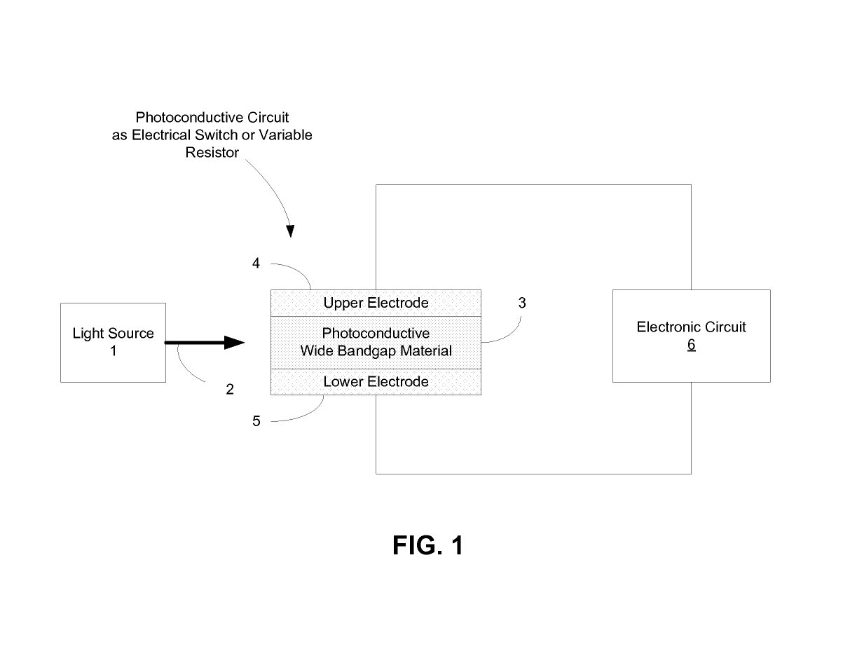

FIG. 1 shows an example of a photoconductive circuit based on a PWBSM which can be used as an electrical switch, a variable resistor, or other functional circuit elements such as signal modulators or amplifiers. This circuit uses a wide bandgap material 3, which can be SiC in some implementations and can absorb radiation such as light to produce charged carriers to change the resistance or the electrical conductivity of the wide bandgap material 3. As illustrated, the circuit includes a substrate of the photoconductive WBG material 3 placed in contact with and located between two electrodes: the upper electrode 4 and the lower electrode 5. A control circuit 6 is coupled to the electrodes 4 and 5 to supply the electrical power to the electrodes 4 and 5, e.g., a voltage. In absence of light or at a low light level below a threshold, the photoconductive WBG material 3 can behave as an insulator with a large resistance value (e.g., much larger than the circuit impedance) and thus essentially blocks the current flow across the two electrodes 4 and 5 in contact with the photoconductive WBG material 3. When optical energy is directed into the WBG material 3 and absorbed, for example, the WBG material 3 produces charge carriers from the absorbed light to become electrically conductive and the resistance drops to a small value (much less than the circuit impedance). The radiation for causing photoconductivity in a PWBSM may be an optical wave or an electromagnetic wave outside the optical spectrum. Furthermore, any type of radiation capable of sufficiently exciting the charge carriers in the wide bandgap material may be used to modulate the conductance response of the PWBSM variable resistor, including electromagnetic radiation, and particle radiation, including for example, electron, proton, neutron, etc.

In the circuit shown in FIG. 1, a light source 1 is provided to produce light 2 for optically activating the WBG material 3. The optical power and the timing or duration of the optical power in the light 1 can be controlled to control or modulate the conductivity of the WBG material 10 to control the electrical output of the circuit. In some implementations, one or more radiation beams can be used to illuminate the WBG material. For example, the input may be made with a multiplicity of optical inputs so that a combination of the effects of the multiple optical inputs occur simultaneously on the output. The switching time of such an exemplary WBG photoconductive switch can be short, e.g., several nanoseconds in some implementations. The exemplary photoconductive switches can be designed and structured to handle high voltages and high currents with reduced inductance to provide rapid switching operations or modulation operations, and precise temporal control.

For example, a photoconductive wide bandgap semiconductor material (PWBSM) can be implemented in various modulation circuits to modulate electrical signals by modulating the conduction response of the PWBSM. This is made possible by the demonstrated transconductance-like properties of PWBSM materials, which have shown fast (<1 ns rise-time), high voltage (>15 kV/mm), high current (>1 kA/cm²), and phototransistor-like modulation capabilities at high modulation frequencies (e.g., greater than 300 MHz and at GHz level), such as for example, in a compact, stacked, transmission-line structure. This capability enables various applications for direct manipulation of high voltage electrical signals. Application examples include, for example, compact high power microwave or RF generation, and energy-modulation of charged particle beams (without use of the photoelectric effect) in directed energy systems, i.e. pulsed power for accelerators and other scientific instruments. See, U.S. Pat. No. 8,563,930 entitled “System and method of modulating electrical signals using photoconductive wide bandgap semiconductors as variable resistors” and issued on Oct. 22, 2013 to assignee Lawrence Livermore National Security, LLC, which was previously published as U.S. Patent Application Publication No. US 20090261258 A1 on Oct. 22, 2009. The entire disclosures of U.S. Pat. No. 8,563,930 and U.S. Patent Application Publication No. US 20090261258 A1 are incorporated by reference as part of the disclosure of this patent document.

The photoconductivity of SiC and other PWBSMs under optical excitation generally increases with the optical power or energy absorbed by the PWBSM material. This property of PWBSMs can be used to construct a PWBSM circuit to function as radiation (e.g. light)-controlled resistors, whose resistance decreases when the PWBSM is exposed to radiation or when the optical power or energy of the radiation is increased. However, the photoconductivity of SiC and other PWBSMs exhibits a non-saturated, linear response region when the optical power or energy is below a threshold and a saturated region when the optical power or energy is at or beyond the threshold.

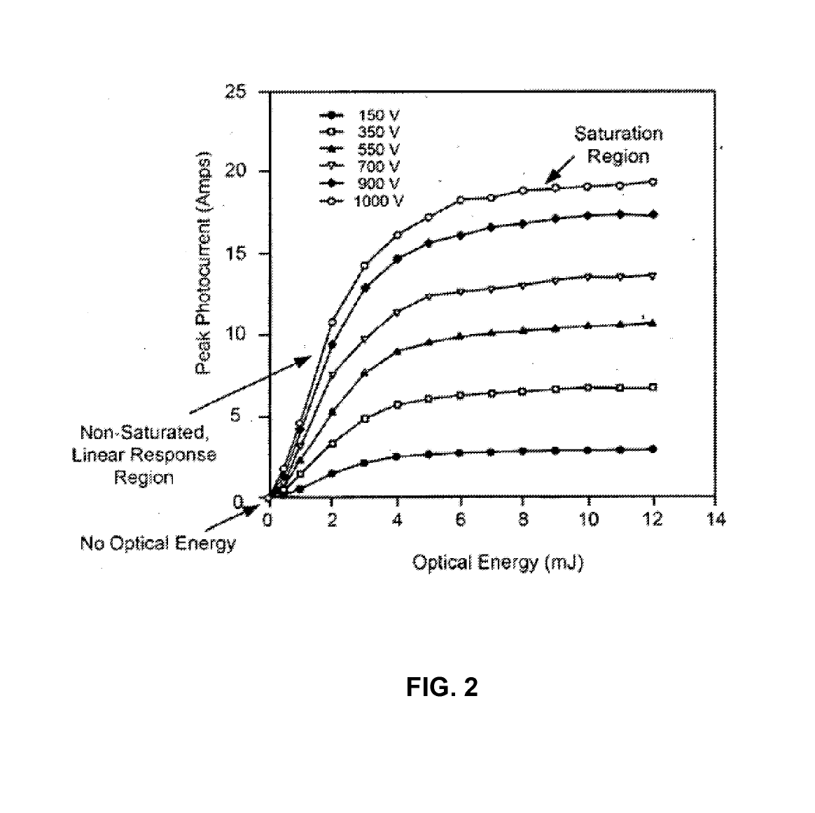

FIG. 2 shows examples of photoconductive currents of SiC under the influence of such visible optical energy at various optical energies and electrical voltages across the SiC from experiments performed by Applicants at Lawrence Livermore National Laboratory. On the x-axis is the intensity of the visible optical energy onto the SiC material. The resultant current flow is shown on the y-axis for multiple voltages applied across the material. FIG. 2 shows details the current through the SiC switch at various voltages resulting from changing the optical intensity to the switch, and shows high current (>1 kA/cm) capability of wide band gap materials (SiC and GaN) under high gradient (>27 MV/m) switching applications. For approximately a change from 0 to 2 mj in optical energy, the device operates in an essentially linear mode from a dark current of about 1 nA to peak current. For this particular data this current was about 20 A at 1 kV. At higher optical energy>2 mJ, a saturation point is reached where the device achieves a minimum resistance of about 1.OMEGA.. The conduction response curve shown in FIG. 2 can be characterized as having a saturated region, and a non-saturated region.

The data in FIG. 2 shows that the non-saturated region has a substantially linear response that is similar to a typical transistor device. The tested SiC material operates with a transconductance like property of the form: Gm=Iout/in, where in is the controlling input parameter. In the case of a simple transistor, .zeta.in, would be the base current or for a vacuum tube, the control grid voltage. For the SiC material, this parameter is the optical or other radiation energy producing a conduction response. Although the very linear, lower current region was illustrated for clarity, SiC exhibits this transconductance property beyond the maximum current greater than 1 kA/cm² in the tested devices. And as with transistor and vacuum tube technologies these materials exhibit a steep high gain linear regime from 0-2 mj and a decreased slope saturation region up to >30 mJ. Thus, when the material is operated in the substantially linear non-saturated region, amplification of an applied modulation to the optical pulse will result in amplification of the applied signal. When properly configured, these switches are able to close and open on timescales of nanoseconds or faster, i.e. high frequency modulation.

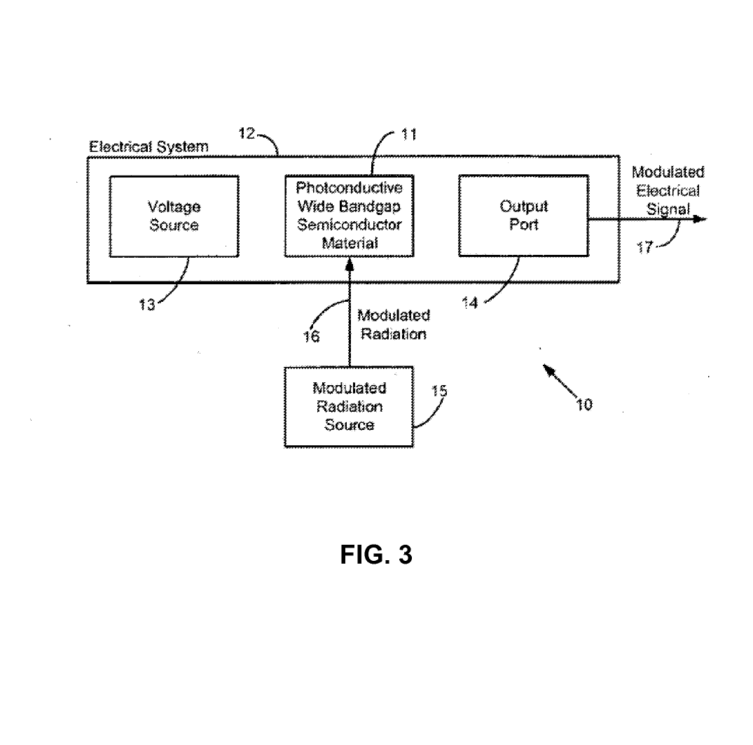

FIG. 3 shows an example of a device for producing modulated electrical signals based on a photoconductive wide bandgap semiconductor material (“PWBSM”) embedded as a variable resistor 11 in an electrical system 12. It is appreciated that the manner of deployment in the electrical system can vary depending on the electrical arrangement of the system, such as in a voltage divider, transmission line, pulse forming line, etc. (to be discussed in greater detail below), and can also be application specific. The PWBSM-based variable resistor 11 is operably connected to both a voltage source 13 and an output port 14 so that an electrical signal 17 is produced at the output port by way of the variable resistor 11. The electrical signal is either generated by activation/modulation of the variable resistor or propagated to simply pass through “via” the variable resistor 11. The output port 15 can include two output terminals/electrodes.

In the example in FIG. 3, the system 10 includes a modulated radiation source, indicated at reference character 15, which produces modulated radiation 16 that is directed upon the variable resistor 11 to modulate its conduction response. The PWBSM variable resistor has a continuous conduction response characterized by a saturation region and a non-saturation region. And in the non-saturation region of operation/activation the conduction response is substantially linear. As such, the modulated radiation 16 produced by the modulated radiation source 15 preferably operates to modulate the conduction response of the variable resistor in the substantially linear region, and thereby operate is a manner similar to an amplifier/transistor. It is notable that the variable resistor is not used as a switch which implies bi-stable “on” and “off” operation. The modulated radiation source 15 of FIG. 3 generally functions to generate and amplitude-modulate radiation, which may be either electromagnetic radiation, e.g. visible light or x-ray, or particle radiation, e.g. electron, proton, or neutron. Thus, the modulated radiation source may produce, for example, an optical pulse train (from a laser) to be directed upon a single PWBSM variable resistor to produce high voltage output pulse train, or a continuously variable analog light signal to be directed upon a single PWBSM variable resistor.

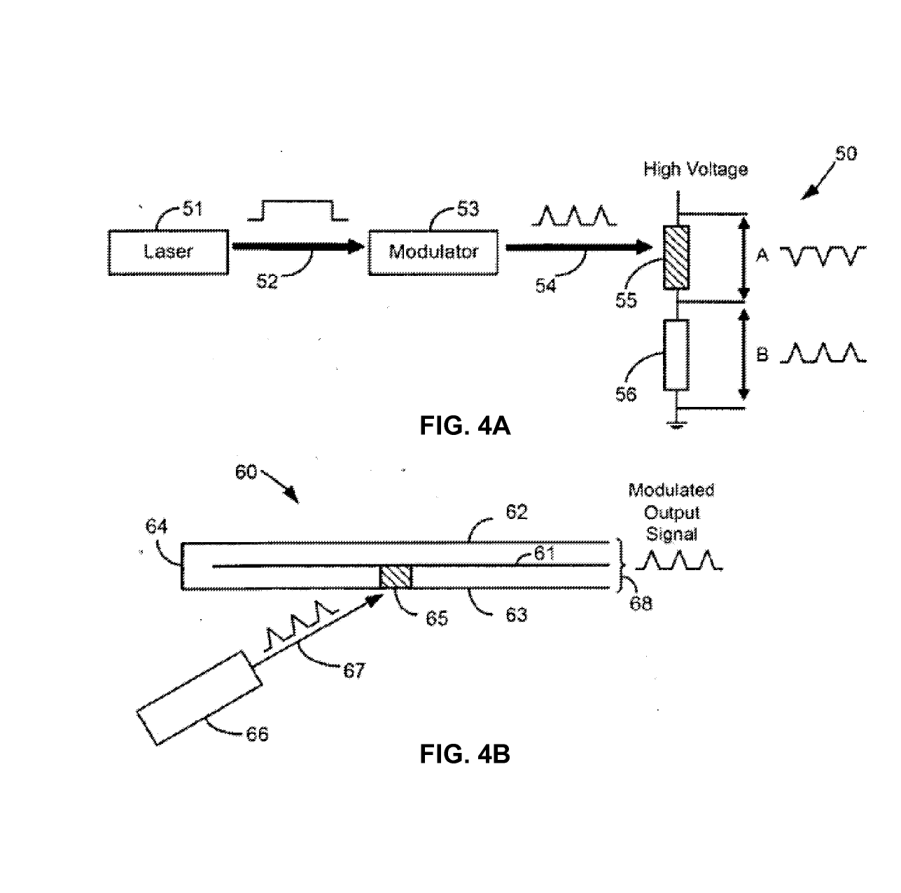

FIGS. 4A and 4B illustrate two examples of devices based on the conduction response of the PWBSM variable resistor to generate a modulated electrical signal at the output port. A PWBSM variable resistor is able to quickly go from high impedance to low impedance in a manner analogous to the operation of a transistor. Generally, in this approach, a laser or other appropriate radiation source is used to produce radiation of a type and amplitude (e.g. intensity) which is sufficient to activate the switch. A modulator (e.g. an optical modulator) is then used to convert the laser light into the correct pulse shape. This could be accomplished, for example, by an acoustic optical modulator, a series of mirrors and optical delay lines, Pockels cells, or other techniques.

In the device in FIG. 4A, device 50 is arranged as a voltage divider in which the PWBSM variable resistor 55 is serially arranged between a voltage source (shown as a high voltage source) and a load 56, which may be a load resistor. A laser 51 is shown generating an unmodulated optical signal 52 which is modulated by optical modulator 53 to produce a modulated optical signal 54, which in turn is directed upon the PWBSM variable resistor 55. A modulated electrical signal is produced across the PWBSM variable resistor 55 at output port A, as well as across the load 56 at output port B.

FIG. 4B illustrates a PWBSM device 60 by coupling a PWBSM 65 in a transmission line configuration. A pulse forming line is used to generate the modulated electrical signal at an output port 68. The pulse forming line shown forms a transmission line which includes a center electrode 61 that is a pre-charged to a voltage by connection to a voltage source (not shown). The other two electrodes 62 and 63 on opposite sides of the pre-charged electrode 61 are held at a ground potential, with the electrodes 61 and 63 electrically connected by backshort 64. The PWBSM 65 is coupled between the pre-charged electrode 61 and the electrode 63. With this arrangement, when amplitude-modulated radiation 67 generated by modulated radiation source 66 is directed upon the PWBSM 65, a modulated pulse is generated at the output port 68. While three electrodes 61, 62 and 63 are shown in the pulse transmission line FIG. 4B, it is appreciated that at least two electrodes may generate a pulse.

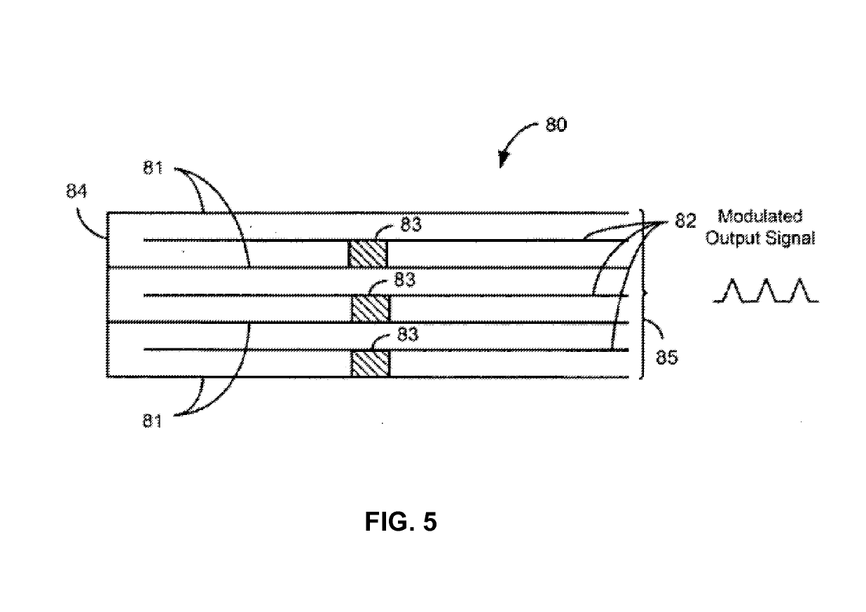

FIG. 5 is an example of a modulation device 80 having multiple PWBSM variable resistors 83 coupled to stacked pulse forming lines of precharged center electrodes 82, and grounded electrodes 81 which are connected by backshort 84 so that the modulated signal at the output port 85 is additive. This device 80 can be used to produce a higher voltage or current modulation signal by adding signals from multiple stages together. In particular, the device in FIG. 5 can be used in a dielectric wall accelerator or an inductive voltage adder configuration which uses stacks of transmission lines to apply voltage to a central conductor (or charged particle beam).

The high electric field levels and current densities in PWBSM devices disclosed in this document present a unique technical issue in managing localized high field spots at the interfaces between the electrodes and the PWBSM material surfaces. For example, a failure in a PWBSM material can be attributed to electric field enhancements due to a localized increase in the electric field above the global average electric field. This electric field enhancement can be characterized as the ratio of the maximum electric field divided by the average electric field. When the enhanced electric field exceeds the electric field strength of the PWBSM material, the material can fail by electrical breakdown. Thus, electric field enhancements must be minimized in PWBSM materials in the devices or circuits disclosed herein.

One method to minimize these enhancements in the PWBSM is by implementing a planar geometry for at least one of the electrodes. Referring to FIG. 5 above, multiple PWBSM variable resistors are embedded in stacked pulse forming lines so that the modulated signal at the output port is additive. This arrangement can be used in a dielectric wall accelerator geometry described in U.S. Pat. No. 7,173,385, entitled “COMPACT ACCELERATOR”, of which the entire content of the aforementioned patent document is incorporated by reference as part of the disclosure of this patent document. The electric field is uniform with an enhancement approaching 1.0. Non-theoretically, the field at the edge of the strips can result in enhancements, but can be suitably managed by adding a curvature such that the plane of the strip is tangent to the curvature. Although, it would be very difficult to achieve an enhancement approaching 1.0 with such a geometry, an enhancement of less than 2.5 would certainly be useful in many practical devices.

By contrast, the use of “leads” like those shown in U.S. Pat. No. 3,192,387 by Goodman, entitled “ELECTRO-OPTICAL DEVICE FOR PRODUCING A MODULATED VOLTAGE”, becomes inherently problematic when used with the high field and current density capability of the PWBSM. For example, “leads” generally have small aspect ratios (e.g., width divided by the height of the conductor). Typically, leads would have aspect ratios of 1.0 to 2.0 whereas strips would have aspect ratios of 5.0 and greater.

In a high electric field, applications such as the PWBSM is capable of, lead type conductors will generate an enhanced electric field and would nullify the advantages of the PWBSM. For example, in such a geometry, the electric field enhancement increases as a log function for smaller conductors and thus is not well suited for a high electric field devices. It is understandable why Goodman did not anticipate the aforementioned problems with this type of geometry simply because of the breakdown voltages of photosensitive means available during that time were very limited. For example, it is understood that CdSe begins to show initial breakdown type behavior at electric fields less that 10 V/mm. That electric field level is at least four orders of magnitude less than that of an exemplary PWBSM. Thus, to achieve a high field within a PWBSM, modifications are required in that geometry to carefully ensure that enhanced electric fields are eliminated. Further, the typical on resistance of the materials that Goodman cites are on the order of 100-200 ohm resistance. Devices of Goodman can only operate at a low electric fields, and practical currents are well below 1 ampere. However, because the PWBSM can be operated at high fields with low on resistance, currents can be very significant. Thus, technology is required to ensure that the currents are relatively uniform.

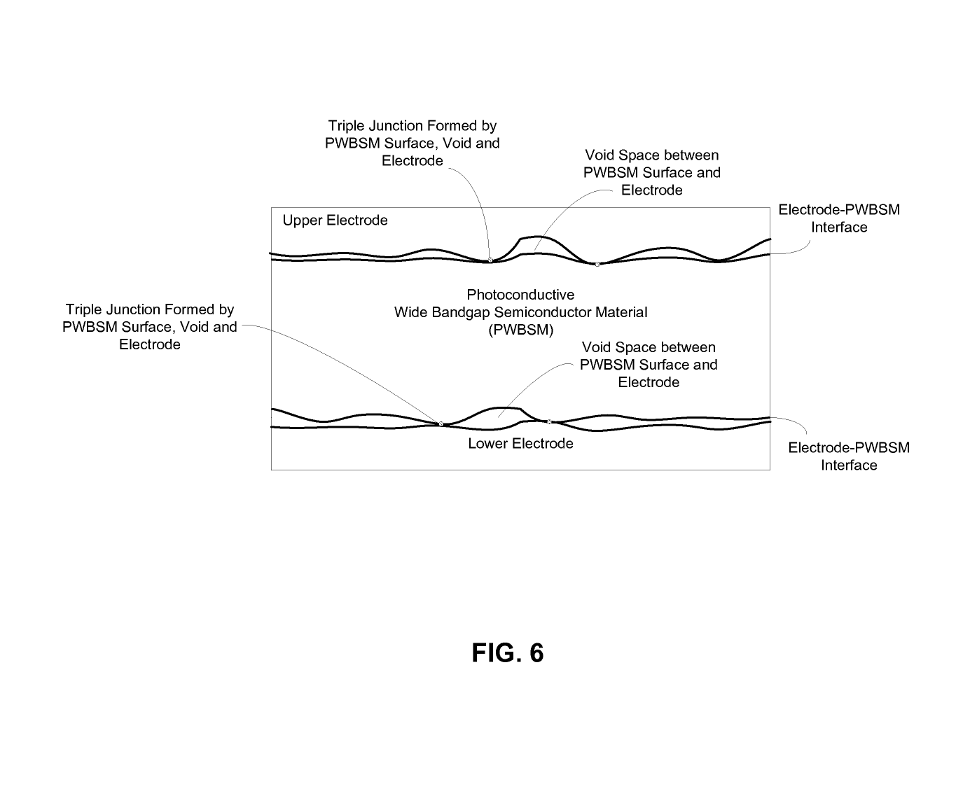

FIG. 6 illustrates examples of typical interfaces between the electrodes and the PWBSM surfaces in PWBSM devices in FIGS. 1-5. In general, two imperfect planes that are non-deformable may only contact at only limited number of contact points, e.g., three points. A PWBSM material tends to be extremely rigid. Likewise, commonly used electrode materials, e.g., such as brass, copper, or similar metals, are also very rigid. Because of the brittleness of the PWBSM, applying increased pressure in an attempt to make more points contact the electrodes could potentially fracture the material. Thus, only these infinitesimally small points form the current contact. As such, the electrode-PWBSM interface tends to have direct contacts at limited locations across the surfaces of electrodes and PWBSM surfaces. At each of such contact points, a tripper junction is formed by the PWBSM surface, the electrode surface and a space near the contact point formed by the space between the PWBSM and electrode. As a result, such contact locations are subject to electric field enhancements and tend to suffer breakdown. As a result, extremely high current densities result at these points and can cause local Joule heating and initiate destruction of the PWBSM. To alleviate this problem, the current contact with the PWBSM must be conformal to the surfaces. This conformal electrode can be an intermediate conductive film to which more rigid electrodes can be attached with solder other suitable attachment methods.

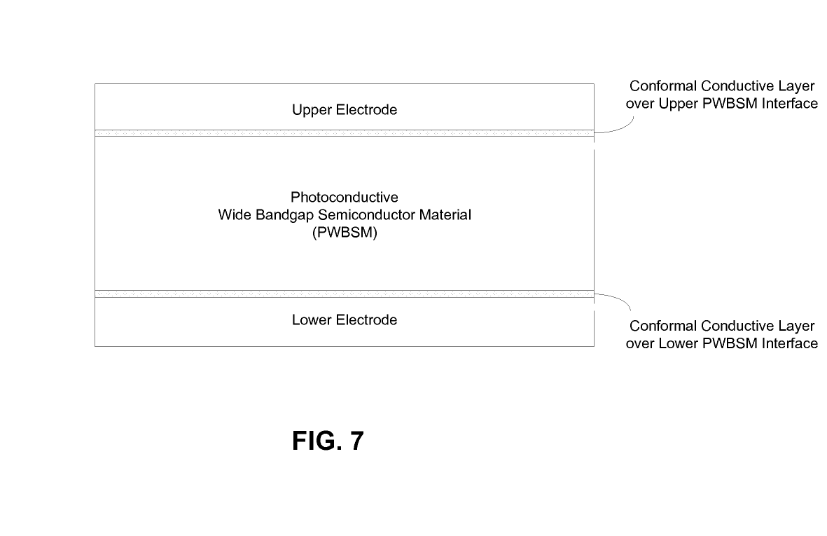

FIG. 7 illustrates an example of a conformal conductive layer over a PWBSM surface as an interface with the electrode in PWBSM devices. The formation of this conformal conductive layer over the PWBSM surface is to make the PWBSM surface itself in contact with an electrode to be electrically conductive to reduce or eliminate localized field enhancements caused imperfections at the interfaces between the electrode and the PWBSM surface. The PWBSM surface can be made electrically conductive by forming a conductive layer over the PWBSM surface to conform with the PWBSM surface and to cover the PWBSM surface by using a suitable deposition or layer forming process. Examples of such a process include ion implantation, deposition of a metal, or deposition of a more reactive material so that by using an added process where a conductive compound can be integrated into the surface. Once this conforming conductive layer is formed on the PWBSM, an electrode layer is formed over the conforming conductive layer which may have a non-conforming electrode surface which is abutted to the conforming conductive layer. The contacting surface of the electrode and the conforming conductive layer in direct contact with the electrode tend to have an interface that has various contact points and voids between them due to the imperfections or non-flat features on their respective surfaces.

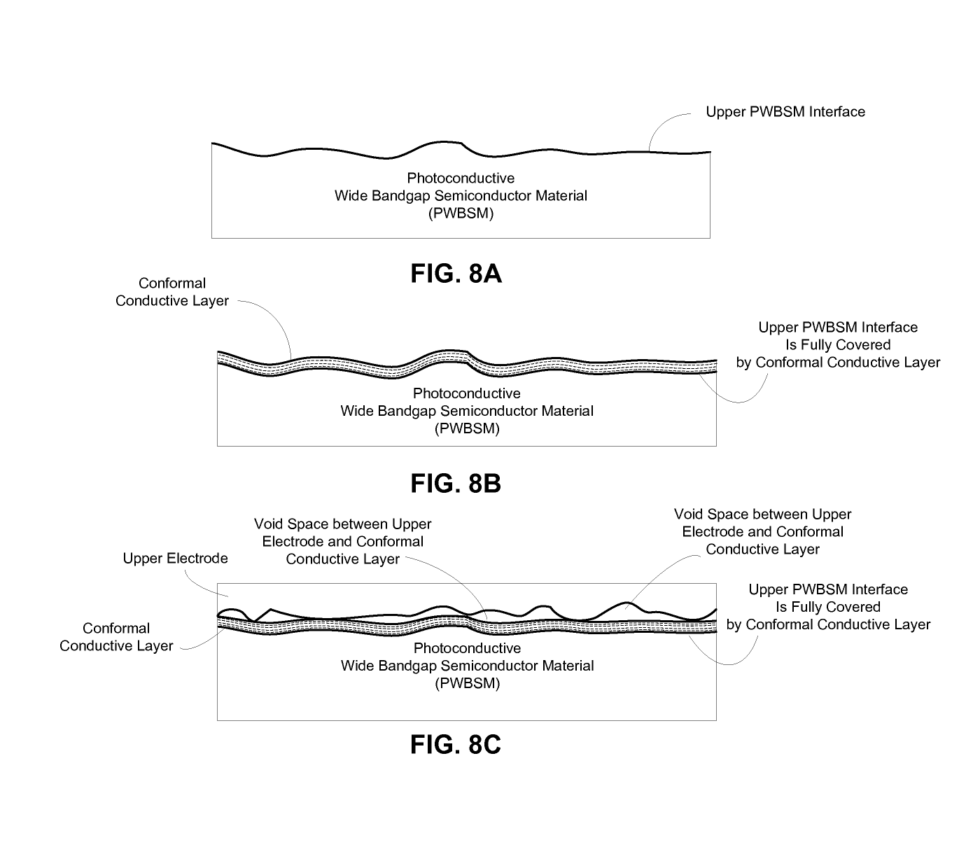

FIGS. 8A, 8B and 8C shows an example of a process for forming the conformal conductive layer and subsequent formation of the electrode by using the upper PWBSM surface as an example. First, as shown in FIG. 8A, the PWBSM is prepared which tends to have a surface that includes some imperfections. Next, a conformal conductive layer is formed over the PWBSM surface to fully cover the PWBSM surface. As such the coated PWBSM surface is now electrically conductive and thus has substantially equal electrical potential throughout the surface of the conformal conductive layer. Due to the conforming nature of the conductive layer, the surface of the conductive layer substantially mirrors the surface profile of the original PWBSM surface and thus contains non-flat surface features or imperfections as illustrated in FIG. 8B. FIG. 8C shows that, subsequent to formation of the conformal conductive layer over the PWBSM surface, an electrode is placed over and engaged to the conformal conductive surface over the PWBSM surface as one electrode for the PWBSM device. As illustrated in FIG. 8C, the contacting surface of the electrode in contact with the conforming conductive layer may not be completely flat and may have surface imperfections which are in direct contact with the surface of the conformal conductive layer which also includes surface imperfections. Therefore, the interface formed between the contacting surface of the electrode and the conformal conductive layer tends to have various contact points and voids between them due to the imperfections or non-flat features on their respective surfaces. Electrical properties of such contact points and voids at the interface between the contacting surface of the electrode and the conformal conductive layer in the structure in FIG. 8C are very different from the electrical properties of the contact points and voids at the interface between the contacting surface of the electrode and the uncoated or bare PWBSM surface in FIG. 6.

Referring back to FIG. 6, the contact points and voids at the interface between the contacting surface of the electrode and the uncoated or bare PWBSM surface have triple junctions where the electrode portion has a different electrical potential from a portion of the bare PWBSM surface or the space. As such, this triple junction tends to cause electrical field enhancements at tips or sharp protrusions of the electrode surface such as a contact point. This condition can lead to undesired electrical breakdown.

In contrast, the contact points and voids at the interface between the contacting surface of the electrode and the conformal conductive layer in the structure in FIG. 8C are very different in that (1) the contacting surfaces of the electrode and the conformal conductive layer are electrically conductive and each contacting surface is an equal electrical potential surface and (2) that two contacting surfaces have some contacts with each other. Therefore, there is not a tripper junction formed in FIG. 8C. Notably, as a result of the above properties, the surfaces surrounding the contact points and voids at the interface between the contacting surface of the electrode and the conformal conductive layer in the structure in FIG. 8C are at an equal electrical potential across the interface between the electrode and the PWBSM surface. Therefore, the undesired localized electrical field enhancements present in FIG. 6 do not exist or are substantially minimized. The combined surfaces at the interface between the contacting surface of the electrode and the conformal conductive layer in the structure in FIG. 8C form an equi-potential structure so that breakdown cannot occur in the gaps between both surfaces despite the presence of the surface variations or imperfections on the surface of the electrode or the PWBSM surface or both.

For better mechanical stability and thermal conductivity, the gaps at the interface between the contacting surface of the electrode and the conformal conductive layer in the structure in FIG. 8C may also be filled with a softer material such as indium or a soft solder alloy.

Therefore, disclosed are devices, systems, and techniques that can be implemented to ensure that the electric field within an exemplary PWBSM is sufficiently uniform so that the performance of a PWBSM-device is not degraded by localized contact points that are subject to electric field enhancements and breakdown. Further, the disclosed technology can be implemented to ensure that there are no current flow concentrations so as to cause extreme localized heating which can lead to vaporization of electrode material and PWBSM, e.g. as such heating will result in eventual catastrophic failure within a device.

In one aspect, an optical transconductance variable resistor includes a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor, and first and second electrodes in contact with the material so that: a first triple junction boundary region is formed between the PWBSM substrate and the first electrode, and a second triple junction boundary region is formed between the PWBSM substrate and the second electrode, and the PWBSM substrate is located within an internal triple junction region formed between the first and second triple junction boundary regions.

In some implementations of the optical transconductance variable resistor, for example, the region outside the internal triple junction region is an insulator.

In another aspect, an optical transconductance variable resistor includes a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor, a first electrode and a second electrode in contact with the photoconductive wide bandgap semiconductor material, and in which one of the first and the second electrodes includes at least one aperture to control radiation to within a volume bounded by a triple junction region. In some examples, the triple junction region is formed between a first triple junction region and a second triple junction region, in which the first triple junction region is formed between the PWBSM substrate and the first electrode, and the second triple junction boundary region is formed between the PWBSM substrate and the second electrode.

In some implementations of the optical transconductance variable resistor, for example, the variable resistor can further include a diffusion/dispersion structure is coated with a reflective coating to reflect radiation toward the substrate. In such implementations, for example, the variable resistor can further include a tapered light pipe connected to the at least one radiation aperture of the electrodes for diffusing/dispersing radiation prior to entering the aperture. In such implementations, for example, the electrode having aperture can expand, diffuse, and/or disperse the radiation into the triple junction region. In some implementations of the optical transconductance variable resistor, for example, the other electrode not having the aperture is reflective at the electrode-substrate interface.

In another aspect of the disclosed technology, a system for producing modulated electrical signals includes a variable resistor including a photoconductive wide bandgap semiconductor material (PWBSM) whose conduction response to changes in amplitude of incident radiation is substantially linear throughout a non-saturation region thereof to enable operation in non-avalanche mode, a modulated radiation source for producing amplitude-modulated radiation with which to direct upon the variable resistor and modulate the conduction response thereof, and a voltage source and an output port, both operably connected to the variable resistor so that an electrical signal produced at the output port by way of the variable resistor is modulated by the variable resistor so as to have a waveform substantially similar to the amplitude-modulated radiation. The variable resistor includes a first electrode and a second electrode electrically coupled to opposite ends of the PWBSM via a conformal conductive material configured between the electrodes and the PWBSM, in which the conformal conductive material provides a uniform electrical contact over substantially the conducting face of the PWBSM.

In some implementations, for example, the system also can include a unit for relieving the enhancement of the electric field in the PWBSM, in which at least one of the electrodes is used to shape the electric field and is generally planar, convex, concave, or combination thereof. In such implementations, for example, the electrodes can be configured to be generally planar and the combination of concave and convex surfaces maintain an electric field enhancement of less than 2.5

In some implementations of the system, for example, the amplitude-modulated radiation produced by the modulated radiation source modulates the conduction response of the variable resistor within the non-saturation region thereof.

In some implementations of the system, for example, the modulated radiation source is of a type selected from a group consisting of a modulated electromagnetic radiation source, and a modulated particle radiation source. In some implementations of the exemplary system, for example, the modulated electromagnetic radiation source is a modulated light source including: a light source for producing a light beam capable of producing the conduction response in the variable resistor; and an optical modulator for intensity-modulating the light beam. In some implementations of the exemplary system, for example, the modulated electromagnetic radiation source is a modulated x-ray source including: a cathode; an anode conversion target; and a grid electrode for modulating electron production at the cathode with which to direct upon the anode conversion target to produce intensity-modulated x-rays therefrom with which to direct upon the variable resistor to modulate the conduction response thereof. In some implementations of the exemplary system, for example, the modulated particle radiation source can include a radioactive source and a particle modulator for modulating the radioactive particles therefrom with which to direct upon the variable resistor to modulate the conduction response thereof. In some implementations of the exemplary system, for example, the modulated particle radiation source is a modulated electron source including: a cathode; and a grid electrode for modulating electron production at the cathode with which to direct upon the variable resistor to modulate the conduction response thereof. In some implementations of the exemplary system, for example, the modulated particle radiation source can include a particle radiation source having a pointed tip and a particle modulator for modulating the extraction of particles therefrom.

In some implementations of the system, for example, the voltage source, the variable resistor, and the output port are operably connected so that modulating the conduction response of the variable resistor with the amplitude-modulated radiation generates the modulated electrical signal at the output port. In one such implementations for example, the system can further include a load serially connected to the variable resistor with the output port electrically connected across one of the load and the variable resistor. In such implementations, for example, the system can further include a second output port electrically connected across the other one of the load and the variable resistor. In another such implementation, for example, the system can further include a triode including: an anode having an associated voltage Vₐ, a cathode having an associated voltage V_{c}, and a grid electrode having an associated voltage V_{g} for controlling triode operation, with the output port connected to one of the anode, the cathode, and the grid electrode to modulate a corresponding one of the voltages Vₐ, V_{c}, or V_{g}.

In another such implementation, for example, the system can further include a pulse forming line having a first conductor connected to and pre-charged by the voltage source, and a second conductor parallel to the first conductor and at ground potential, the output port including adjacent output ends of the first and second conductors, and the variable resistor bridging the first and second conductors at a removed location from the output ends. For example, the pulse forming line can have a third conductor parallel to the first conductor and opposite the second conductor, in which the third conductor has an output end adjacent the output end of the first conductor and electrically connected to the second conductor at a removed location from the output ends. In such implementations, for example, the system can further include at least one additional pulse forming line in stacked arrangement with the pulse forming line so that the modulated electrical signals produced at the respective output ports are additive.

In some implementations of the system, for example, the voltage source is a pulse generator, and the system further can include a transmission line having an input end connected to the pulse generator, an output end including the output port, and a photoconductivity-modulated inline section including the variable resistor located between the input and output ends, for propagating an incident voltage pulse from the input end to the output port via the photoconductivity-modulated section, so that modulating the conduction response of the variable resistor with the amplitude-modulated radiation substantially impresses the waveform of the amplitude-modulated radiation to transmitted and reflected portions of the incident voltage pulse. For example, in such implementations, the photoconductivity-modulated section of the transmission line, when not activated, has a matching impedance with adjacent sections of the transmission line so as to pass the incident voltage pulse without reflection. For example, in such implementations, the transmission line can include at least one additional photoconductivity-modulated inline section including another variable resistor, with the modulated radiation source directing the amplitude-modulated radiation to all the photoconductivity-modulated sections. In some implementations, for example, the transmission line can include at least one additional photoconductivity-modulated inline section including another variable resistor, in which the system can further include at least one additional modulated radiation source for producing amplitude-modulated radiation independently of the other modulated radiation source with which to direct upon the additional photoconductivity-modulated section. In some implementations, for example, the system can further include a second output port at the input end of the transmission line for emitting the reflected portions of the incident voltage pulse.

In some implementations of the system, for example, the system can further include at least one additional variable resistor and associated output port; and a phase controller for controlling the phase of a corresponding amplitude-modulated radiation directed upon the respective variable resistors so as to control the phase of the modulated electrical signals at the respective output ports.

In some implementations of the system, for example, the system can further include a transmission device connected to the output port for transmitting the modulated electrical signal. For example, the transmission device can be an antenna. For example, the modulated radiation source produces the amplitude-modulated radiation at a microwave frequency, so that a microwave signal is transmitted via the antenna.

In some implementations of the system, for example, the system can further include an evacuated dielectric wall beam tube having an input end for receiving charged particles, the output port connected along the beam tube so that charged particles present in the beam tube receive an energy modulation corresponding to the modulated electrical signal at the output port so as to produce a modulated charged particle beam.

In another aspect, a method of the disclosed technology for producing modulated electrical signals includes providing a voltage source, an output port, and a variable resistor operably connected to the voltage source and the output port so that an electrical signal is produced at the output port by way of the variable resistor, the variable resistor comprising a photoconductive wide bandgap semiconductor material (PWBSM) whose conduction response to changes in amplitude of incident radiation is substantially linear throughout a non-saturation region thereof, whereby the variable resistor is operable in non-avalanche mode; and directing upon the variable resistor amplitude-modulated radiation produced by a modulated radiation source to modulate the conduction response of the variable resistor, so that the electrical signal produced at the output port is modulated by the variable resistor so as to have a waveform substantially similar to the amplitude-modulated radiation.

In another aspect, a photoconductivity-modulated variable resistor device of the disclosed technology includes a photoconductive wide bandgap semiconductor material (PWBSM) whose conduction response to changes in amplitude of incident radiation is substantially linear throughout a non-saturation region thereof, whereby the PWBSM is operable in non-avalanche mode as a variable resistor; and a modulated radiation source for producing amplitude-modulated radiation with which to direct upon the PWBSM so that the conduction response induced thereby in the PWBSM has a waveform substantially similar to the amplitude-modulated radiation.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A system for producing modulated electrical signals, comprising:
a variable resistor comprising a photoconductive wide bandgap semiconductor material (PWBSM) whose conduction response to changes in amplitude of incident radiation is substantially linear throughout a non-saturation region thereof to enable operation in non-avalanche mode, the variable resistor including a first electrode and a second electrode electrically coupled to opposite ends of the PWBSM via a conformal conductive material between the electrodes and the PWBSM, wherein the conformal conductive material provides a uniform electrical contact over substantially the conducting face of the PWBSM;
a modulated radiation source for producing amplitude-modulated radiation with which to direct upon the variable resistor and modulate the conduction response thereof; and
a voltage source and an output port, both operably connected to the variable resistor so that an electrical signal produced at the output port by way of the variable resistor is modulated by the variable resistor so as to have a waveform substantially similar to the amplitude-modulated radiation.

2. The system of claim 1, wherein the first and second electrodes are configured to be in contact with the material so that: a first triple junction boundary region is formed between the PWBSM and the first electrode, and a second triple junction boundary region is formed between the PWBSM and the second electrode, and the PWBSM is located within a triple junction region formed between the first and second triple junction boundary regions.

3. The system of claim 1, wherein at least one of the electrodes is configured in a shape including generally planar, convex, concave, or combination thereof to relieve the enhancement of the electric field.

4. The system of claim 3, wherein the electrodes are substantially planar and the combination of concave and convex surfaces maintain an electric field enhancement of less than 2.5.

5. The system of claim 1, wherein the amplitude-modulated radiation produced by the modulated radiation source modulates the conduction response of the variable resistor within the non-saturation region thereof.

6. The system of claim 1, wherein the modulated radiation source is of a type selected from a group consisting of a modulated electromagnetic radiation source, and a modulated particle radiation source.

7. The system of claim 6, wherein the modulated electromagnetic radiation source is a modulated light source comprising: a light source for producing a light beam capable of producing the conduction response in the variable resistor; and an optical modulator for intensity-modulating the light beam.

8. The system of claim 6, wherein the modulated electromagnetic radiation source is a modulated x-ray source comprising: a cathode; an anode conversion target; and a grid electrode for modulating electron production at the cathode with which to direct upon the anode conversion target to produce intensity-modulated x-rays therefrom with which to direct upon the variable resistor to modulate the conduction response thereof.

9. The system of claim 6, wherein the modulated particle radiation source comprises a radioactive source and a particle modulator for modulating the radioactive particles therefrom with which to direct upon the variable resistor to modulate the conduction response thereof.

10. The system of claim 6, wherein the modulated particle radiation source is a modulated electron source comprising: a cathode; and a grid electrode for modulating electron production at the cathode with which to direct upon the variable resistor to modulate the conduction response thereof.

11. The system of claim 6, wherein the modulated particle radiation source comprises a particle radiation source having a pointed tip and a particle modulator for modulating the extraction of particles therefrom.

12. The system of claim 1, wherein the voltage source, the variable resistor, and the output port are operably connected so that modulating the conduction response of the variable resistor with the amplitude-modulated radiation generates the modulated electrical signal at the output port.

13. The system of claim 12, further comprising:
a load serially connected to the variable resistor with the output port electrically connected across one of the load and the variable resistor.

14. The system of claim 13, further comprising:
a second output port electrically connected across the other one of the load and the variable resistor.

15. The system of claim 12, further comprising:
a triode comprising an anode having an associated voltage Vₐ, a cathode having an associated voltage V_{c}, and a grid electrode having an associated voltage V_{g} for controlling triode operation, with the output port connected to one of the anode, the cathode, and the grid electrode to modulate a corresponding one of the voltages Vₐ, V_{c}, or V_{g}.

16. The system of claim 12, further comprising:
a pulse forming line having a first conductor connected to and pre-charged by the voltage source, and a second conductor parallel to the first conductor and at ground potential, the output port comprising adjacent output ends of the first and second conductors, and the variable resistor bridging the first and second conductors at a removed location from the output ends.

17. The system of claim 16, wherein the pulse forming line has a third conductor parallel to the first conductor and opposite the second conductor, the third conductor having an output end adjacent the output end of the first conductor and electrically connected to the second conductor at a removed location from the output ends.

18. The system of claim 17, further comprising:
at least one additional pulse forming line in stacked arrangement with the pulse forming line so that the modulated electrical signals produced at the respective output ports are additive.

19. The system of claim 1, wherein the voltage source is a pulse generator, and further comprising:
a transmission line having an input end connected to the pulse generator, an output end comprising the output port, and a photoconductivity-modulated inline section comprising the variable resistor located between the input and output ends, for propagating an incident voltage pulse from the input end to the output port via the photoconductivity-modulated section, so that modulating the conduction response of the variable resistor with the amplitude-modulated radiation substantially impresses the waveform of the amplitude-modulated radiation to transmitted and reflected portions of the incident voltage pulse.

20. The system of claim 19, wherein the photoconductivity-modulated section of the transmission line, when not activated, has a matching impedance with adjacent sections of the transmission line so as to pass the incident voltage pulse without reflection.

21. The system of claim 19, wherein the transmission line includes at least one additional photoconductivity-modulated inline section comprising another variable resistor, with the modulated radiation source directing the amplitude-modulated radiation to all the photoconductivity-modulated sections.

22. The system of claim 19, wherein the transmission line includes at least one additional photoconductivity-modulated inline section comprising another variable resistor, and further comprising:
at least one additional modulated radiation source for producing amplitude-modulated radiation independently of the other modulated radiation source with which to direct upon the additional photoconductivity-modulated section.

23. The system of claim 19, further comprising:
a second output port at the input end of the transmission line for emitting the reflected portions of the incident voltage pulse.

24. The system of claim 1, further comprising:
at least one additional variable resistor and associated output port; and
a phase controller for controlling the phase of a corresponding amplitude-modulated radiation directed upon the respective variable resistors so as to control the phase of the modulated electrical signals at the respective output ports.

25. The system of claim 1, further comprising:
a transmission device connected to the output port for transmitting the modulated electrical signal.

26. The system of claim 25, wherein the transmission device is an antenna.

27. The system of claim 26, wherein the modulated radiation source produces the amplitude-modulated radiation at a microwave frequency, so that a microwave signal is transmitted via the antenna.

28. The system of claim 1, further comprising:
an evacuated dielectric wall beam tube having an input end for receiving charged particles, the output port connected along the beam tube so that charged particles present in the beam tube receive an energy modulation corresponding to the modulated electrical signal at the output port so as to produce a modulated charged particle beam.

29. A method of producing modulated electrical signals, comprising:
providing a voltage source, an output port, and a variable resistor operably connected to the voltage source and the output port so that an electrical signal is produced at the output port by way of the variable resistor, the variable resistor comprising a photoconductive wide bandgap semiconductor material whose conduction response to changes in amplitude of incident radiation is substantially linear throughout a non-saturation region thereof, whereby the variable resistor is operable in non-avalanche mode; and
directing upon the variable resistor amplitude-modulated radiation produced by a modulated radiation source to modulate the conduction response of the variable resistor, so that the electrical signal produced at the output port is modulated by the variable resistor so as to have a waveform substantially similar to the amplitude-modulated radiation.

30. A photoconductivity-modulated variable resistor device, comprising:
a photoconductive wide bandgap semiconductor material (PWBSM) whose conduction response to changes in amplitude of incident radiation is substantially linear throughout a non-saturation region thereof, whereby the PWBSM is operable in non-avalanche mode as a variable resistor; and
a modulated radiation source for producing amplitude-modulated radiation with which to direct upon the PWBSM so that the conduction response induced thereby in the PWBSM has a waveform substantially similar to the amplitude-modulated radiation.

31. An optical transconductance variable resistor, comprising:
a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor; and
first and second electrodes in contact with the material so that: a first triple junction boundary region is formed between the PWBSM substrate and the first electrode, and a second triple junction boundary region is formed between the PWBSM substrate and the second electrode, and the PWBSM substrate is located within an internal triple junction region formed between the first and second triple junction boundary regions.

32. The optical transconductance variable resistor of claim 31, wherein the region outside the internal triple junction region is an insulator.

33. An optical transconductance variable resistor, comprising:
a photoconductive wide bandgap semiconductor material (PWBSM) substrate, whose conduction response to changes in amplitude of incident radiation that is substantially linear throughout a non-saturation region thereof, whereby the material is operable in non-avalanche mode as a variable resistor;
a first electrode and a second electrode in contact with the photoconductive wide bandgap semiconductor material; and
wherein one of the first and the second electrodes includes at least one aperture to control radiation to within a volume bounded by a triple junction region formed between a first triple junction region and a second triple junction region, in which the first triple junction region is formed between the PWBSM substrate and the first electrode, and the second triple junction boundary region is formed between the PWBSM substrate and the second electrode.

34. The optical transconductance variable resistor of claim 33, further comprising;
a diffusion/dispersion structure is coated with a reflective coating to reflect radiation toward the substrate.

35. The optical transconductance variable resistor of claim 34, further comprising:
a tapered light pipe connected to the at least one radiation aperture of the electrodes for diffusing/dispersing radiation prior to entering the aperture.

36. The optical transconductance variable resistor of claim 35, wherein the electrode having the aperture expands, diffuses, or disperses the radiation into the triple junction region.

37. The optical transconductance variable resistor of claim 33, wherein the other electrode not having the aperture is reflective at the electrode-substrate interface.
